(19) United States
(12) Patent Application Publication
(10) Pub. No.: US 2025/0185125 A1
(43) Pub. Date: Jun. 5, 2025

(54) HEATER

(71) Applicant: SAMSUNG ELECTRONICS CO., LTD., Suwon-si (KR)

(72) Inventors: Seungjun Lee, Suwon-si (KR); Rakki Lee, Suwon-si (KR); Junho Im, Suwon-si (KR)

(21) Appl. No.: 18/741,301

(22) Filed: Jun. 12, 2024

(30) Foreign Application Priority Data
Dec. 4, 2023 (KR) 10-2023-0173033

(51) Int. Cl. H05B 3/22; H01L 21/67

(52) U.S. Cl. CPC H05B 3/22; H01L 21/67103

(57) ABSTRACT

A heater is provided, the heater including: a head portion having a first region and a second region disposed outside the first region; a coating film covering at least a portion of an upper surface of the head portion; and a support portion extending from a central portion of the first region of the head portion in a direction perpendicular to a lower surface of the head portion, wherein the coating film includes a first vertical region stacked on an upper surface of the head portion, and having an isotropic texture structure; a second vertical region stacked on an upper surface of the first vertical region, and having a columnar crystal grain structure; and a third vertical region stacked on an upper surface of the second vertical region, and having an isotropic texture structure.

### CROSS-REFERENCE TO RELATED APPLICATION(S)

This application claims benefit of priority to Korean Patent Application No. 10-2023-0173033, filed on Dec. 4, 2023, in the Korean Intellectual Property Office, the disclosure of which is incorporated herein by reference in its entirety.

### BACKGROUND

As heat transfer is required in various deposition processes, a heater is used. During the process, a high-temperature environment may be created, and research on protective coatings is being conducted to prevent the formation of by-products.

### SUMMARY

An aspect of the present disclosure is to provide a heater having improved reliability and a plasma processing apparatus including the same.

According to an aspect of the present disclosure, provided is a heater, the heater including: a head portion having a first region and a second region disposed outside the first region; a coating film covering at least a portion of an upper surface of the head portion; and a support portion extending from a central portion of the first region of the head portion in a direction perpendicular to a lower surface of the head portion, wherein the coating film includes a first vertical region stacked on an upper surface of the head portion, the first vertical region having an isotropic texture structure; a second vertical region stacked on an upper surface of the first vertical region, the second vertical region having a columnar crystal grain structure; and a third vertical region stacked on an upper surface of the second vertical region, the third vertical region having an isotropic texture structure.

According to an aspect of the present disclosure, provided is a heater, the heater including: a head portion; a coating film, wherein the coating film includes a support region formed of first crystal grains and covering at least a portion of the head portion, and includes a crack prevention region formed of second crystal grains and covering at least a portion of the support region; and a support portion extending from the head portion in one direction, wherein an average size of the second crystal grains is greater than an average size of the first crystal grains, and the second crystal grains have a length in a vertical direction greater than a length in a horizontal direction with respect to an upper surface of the head portion.

According to an aspect of the present disclosure, provided is a heater, the heater including: a head portion having a first region and a second region disposed outside the first region; a coating film covering at least a portion of an upper surface of the head portion in the first region; and a support portion extending from a central portion of the first region of the head portion in a direction perpendicular to a lower surface of the head portion, wherein the coating film includes at least one region spaced apart from the upper surface of the head portion, wherein at least the one region formed of crystal grains arranged in a comb-patterned structure.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a schematic cross-sectional view of a plasma processing apparatus according to some implementations of the present disclosure;

FIG. 2A is a perspective view illustrating a heater according to some implementations of the present disclosure, FIG. 2B is a cross-sectional view illustrating the heater of FIG. 2A, and FIG. 2C is a partially enlarged view of region ‘A’ of FIG. 2B;

FIGS. 3A and 3B are scanning electron microscopy (SEM) images of a coating film in a heater according to some implementations of the present disclosure and scanning transmission electron microscopy (STEM) images of a partially enlarged region from SEM, respectively;

FIG. 4A is a graph of X-Ray diffraction (XRD) data of first to third vertical regions of a coating film according to some implementations of the present disclosure; FIGS. 4B and 4C are transmission electron microscopy (TEM) images obtained by taking a first vertical region, FIGS. 4D and 4E are TEM images obtained by taking a second vertical region, and FIGS. 4F and 4G are TEM images obtained by taking a third vertical region;

FIG. 5 is a partially enlarged view of region ‘A’ corresponding to FIG. 2C among the heaters according to some implementations of the present disclosure;

FIG. 6 is a partially enlarged view of region ‘A’ corresponding to FIG. 2C among the heaters according to some implementations of the present disclosure;

FIG. 7 is a cross-sectional view illustrating a heater according to some implementations of the present disclosure;

FIG. 8 is a cross-sectional view illustrating a heater according to some implementations of the present disclosure; and

FIG. 9 is a schematic diagram schematically expressing a manufacturing process of a heater according to some implementations of the present disclosure.

### DETAILED DESCRIPTION

Hereinafter, with reference to the accompanying drawings, implementations will be described as follows. Unless otherwise specified, in this specification, terms such as ‘upper portion,’ ‘upper surface,’ ‘lower portion,’ ‘lower surface,’ ‘side surface,’ and the like, are based on the drawings, and may actually vary depending on a direction in which the components are arranged.

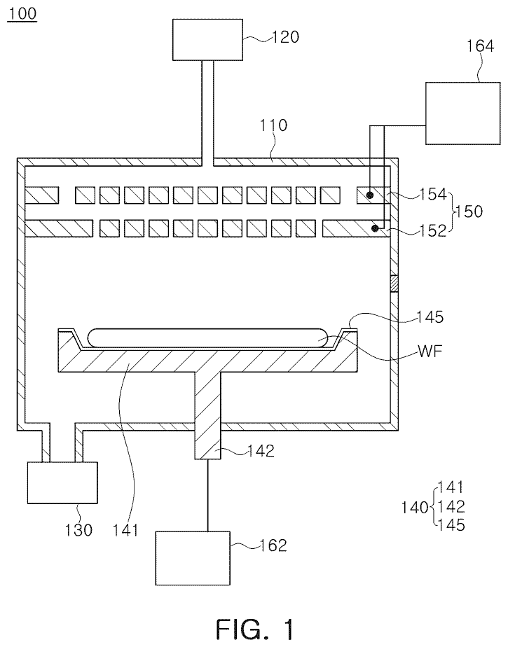

FIG. 1 is a schematic cross-sectional view of a plasma processing apparatus according to some implementations.

Referring to FIG. 1, a plasma processing apparatus 100 includes a chamber 110, a gas supplier 120, an exhaust unit 130, a heater 140, a shower head 150, and first and second power sources 162 and 164. The plasma processing apparatus 100 may be an apparatus for performing a plasma processing process on a wafer WF provided on the heater 140. Depending on implementations, the plasma processing apparatus 100 may be a deposition apparatus or a dry cleaning apparatus.

The chamber 110 may provide a space in which plasma is formed and a space in which a surface processing process is performed. The chamber 110 may provide a sealed internal space in which a wafer WF is processed. The chamber 110 may be provided with a separate passage on one side thereof through which the wafer WF is loaded and unloaded. The chamber 110 may be formed of a metal material, for example, include aluminum (Al) or an alloy thereof.

The gas supplier 120 may supply process gas required for plasma generation, and the process gas may be supplied to a plasma generation region within the shower head 150 or on the shower head 150. The exhaust unit 130 may include an exhaust device for exhausting remaining gas and by-products inside the chamber 110 externally. For example, the exhaust device may include a vacuum pump.

The heater 140 is located below the chamber 110, and may support the wafer WF while the wafer WF is processed. Depending on implementations, the heater 140 may be referred to as a susceptor. Depending on implementations, the heater 140 may be configured to rise and fall. A detailed description of the heater 140 will be described later.

The shower head 150 may be disposed above the heater 140, and plasma generated inside or above the shower head 150 may be distributed and supplied onto the heater 140. The shower head 150 may include, for example, circular plate-shaped distribution plates and a plurality of through-holes formed in each of the distribution plates. The through-holes may be configured to pass a substrate processing material such as plasma, and the substrate processing material may be sprayed onto the wafer WF through the through-holes. In some implementations, the number and shape of distribution plates of shower head 150 are not limited to those shown in FIG. 1. The shower head 150 may include a metal material, for example, aluminum (Al), which is easy to be processed.

The first and second power sources 162 and 164 may supply power required for plasma generation. For example, each of the first and second power sources 162 and 164 may apply radio frequency (RF) power or ground in a form of electromagnetic waves having a predetermined frequency and intensity to the distribution plates of the shower head 150.

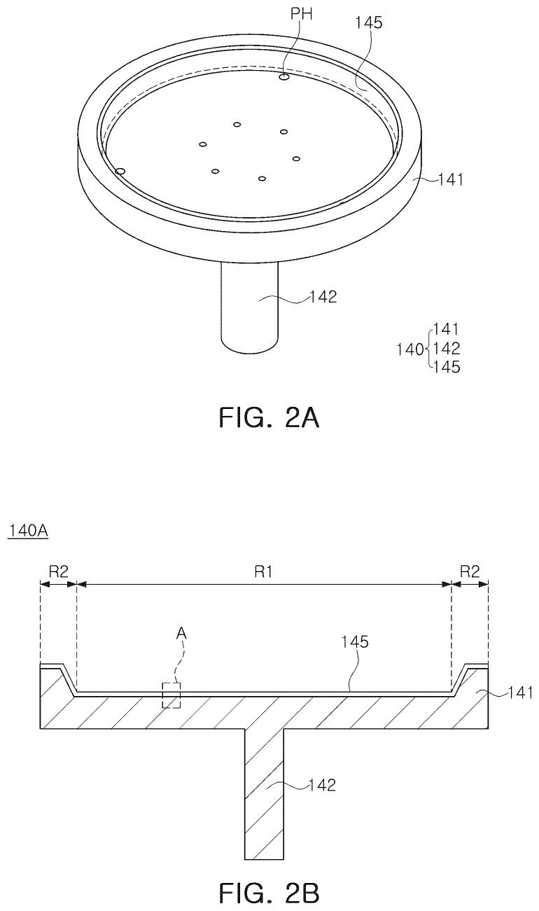

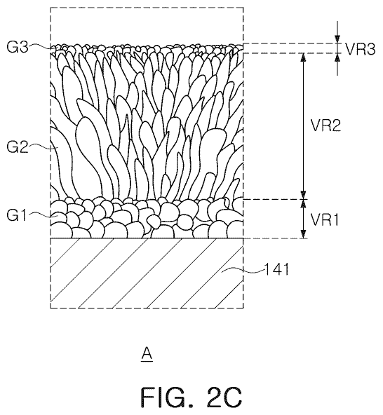

FIG. 2A is a perspective view individually illustrating the heater 140 of the plasma processing apparatus 100 of FIG. 1, FIG. 2B is a cross-sectional view illustrating the heater 140A according to some implementations of the present disclosure, and FIG. 2C is a partial enlarged view of region ‘A’ in FIG. 2B.

Referring to FIGS. 2A to 2C, the heater 140A includes a head portion 141, a coating film 145, and a support portion 142.

The head portion 141 may have a first region R1 and a second region R2 disposed outside the first region R1. The head portion 141 may have a concave shape in which a height of a central portion of the head portion 141 is lower than a height of an edge portion thereof. A horizontal region including the central portion of the head portion 141 may be referred to as a first region R1, and an edge or rim region of the head portion 141 surrounding the first region R1 of the head portion 141 may be referred to as a second region R2. The first region R1 may be a region in which a wafer WF is disposed. The head portion 141 may have a plurality of pinholes PH extending in a direction perpendicular to an upper surface within the first region R1. A plurality of fine pins (not shown) may be disposed inside each of the plurality of pinholes PH, and the fine pins may rise above than the upper surface of the head portion 141 to increase a distance between the head portion 141 and the wafer WF disposed within the first region R1 of the head portion 141. The second region R2 is a region surrounding the first region R1 on a plane, and may be a region surrounding the wafer WF disposed on the upper surface of the head portion 141.

The head portion 141 may be a portion of an aluminum nitride (AlN) heater, but the present disclosure is not limited thereto. Depending on the implementation, the head portion 141 may be a portion of a heater containing a metal oxide such as MgAl₂O₄. A coil, electrode, or the like may be inserted into the head portion 141, and the coil, electrode, or the like inside the head portion may receive energy from the outside, and transfer heat to the wafer WF disposed on the head portion 141, thereby controlling the temperature.

The support portion 142 may extend from the central portion of the first region R1 of the head portion 141 in a direction perpendicular to a lower surface of the head portion 141 (e.g., Z-axis direction). The support portion 142 may serve to control the rise or fall of the head portion 141, and may serve to support the head portion 141 on which the wafer WF is disposed to be fixed within the chamber. In addition, the support portion 142 may be connected to a first power source 162 disposed outside the chamber, and may serve as a passage for supplying an energy source to the head portion 141 from the outside. The support portion 142 may include the same material as the head portion 141.

The coating film 145 may cover at least a portion of an upper surface of the head portion 141. Referring to FIG. 2B, the coating film 145 of the heater 140A according to some implementations of the present disclosure may cover the entire upper surface of the head portion 141 over the first region R1 and the second region R2. The coating film 145 may include Y₂O₃, but the present disclosure is not limited thereto, and depending on the implementations, may include a compound containing yttrium (Y), for example, Yttrium Aluminum Garnet (YAG), YOF, YF₃, or the like. A thickness of the coating film 145 may be about 5 μm or more, about 6 μm or more and 15 μm or less, or about 7 μm or more and 10 μm or less, but implementations are not limited thereto.

The coating film 145 may be disposed on an upper surface of the head portion 141, and include a first vertical region VR1, a second vertical region VR2, and a third vertical region VR3, sequentially formed from the upper surface of the head portion 141. The first to third vertical regions VR1, VR2, and VR3 may include the same material and have the same crystal phase. Specifically, the first to third vertical regions VR1, VR2, and VR3 may have a cubic structure. The coating film 145 may be formed on a surface of the heater 140 containing aluminum nitride (AlN), thereby covering the surface of the heater 140, specifically the head portion 141, so that it is not exposed to the outside. The coating film 145 may prevent the surface of the head portion 141 from being exposed to the outside, thereby preventing by-products (e.g., AlFₓ) from being generated during the process of processing plasma within the chamber.

The first vertical region VR1 is a region disposed at the bottom of the coating film 145, and may be a region in direct contact with the head portion 141. A lower surface of the first vertical region VR1 may be determined according to the surface roughness of the head portion 141. The first vertical region VR1 may be a support region in which the coating film 145 is fixed to the upper surface of the head portion 141. A thickness ratio of the first vertical region VR1 to the entire coating film 145 may be about 12% to 30%, about 15% to 25%, or about 15% to 20%, but implementations are not limited thereto. The first vertical region VR1 may have a dense crystal grain structure, and crystal grains disposed within the first vertical region VR1 may be referred to as first crystal grains G1. The first vertical region VR1 may have an isotropic or non-directional texture structure, and the first crystal grains G1 in the first vertical region VR1 may have a structure in which the first crystal grains G1 in the first vertical region VR1 are not arranged in a specific direction but are spread out. An average size of the first crystal grains G1 in the first vertical region VR1 may be about 10 nm to 25 nm, or about 10 nm to 20 nm, but implementations are not limited thereto.

The second vertical region VR2 is a region disposed in the middle of the coating film 145, and may be a region stacked on the first vertical region VR1. A lower surface of the second vertical region VR2 may be determined according to the surface roughness of the first vertical region VR1. The second vertical region VR2 may be a crack prevention region which prevents cracks from occurring in the coating film 145 in a high temperature environment caused by heat transferred from the head portion 141. A thickness ratio of the second vertical region VR2 to the entire coating film 145 may be about 60% to 85%, about 70% to 80%, or about 75% to 80%, but implementations are not limited thereto. Crystal grains disposed in the second vertical region VR2 may be referred to as second crystal grains. The second vertical region VR2 may have an anisotropic columnar crystal grain structure or a columnar crystal grain structure. Specifically, the second crystal grains G2 may have a length in a vertical direction greater than a length in a horizontal direction with respect to an upper surface of the first vertical region VR1. The second crystal grains G2 may be arranged in a comb-patterned or fan-shaped structure from an interface of the first and second vertical regions VR1 and VR2. An average size of the second crystal grains G2 in the second vertical region VR2 may be larger than the average size of the first crystal grains G1 in the first vertical region VR1. The average size of the second grains G2 in the second vertical region VR2 may be between about 30 nm and 80 nm, or between about 30 nm and 70 nm, but implementations are not limited thereto.

The third vertical region VR3 is a region disposed at the top of the coating film 145, and may be a region in which a wafer is disposed. A lower surface of the third vertical region VR3 may be determined according to the surface roughness of the second vertical region VR2. The third vertical region VR3 may be an auxiliary region which allows the wafer to be stably disposed on the coating film 145. A thickness ratio of the third vertical region VR3 to the entire coating film 145 may be about 3% to 10%, about 3% to 7%, or about 4% to 6%, but implementations are not limited thereto. The third vertical region VR3 may have a dense crystal grain structure, and crystal grains disposed within the third vertical region VR3 may be referred to as third crystal grains G3. Since the third crystal grains G3 have the same or similar characteristics as the first crystal grains G1, the description of the third crystal grains G3 may be replaced with the description of the first crystal grains G1 described above. An average size of the third crystal grains G3 in the third vertical region VR3 may be smaller than the average size of the first crystal grains G1 in the first vertical region VR1. The average size of the third crystal grains G3 in the third vertical region VR3 may be less than about 20 nm or less than about 10 nm, but implementations are not limited thereto.

The coating film 145 may include first to third vertical regions VR1, VR2, and VR3 having different microstructures or different crystal grain sizes, thereby preventing cracks from occurring in the coating film 145 due to heat transferred from the heater 140.

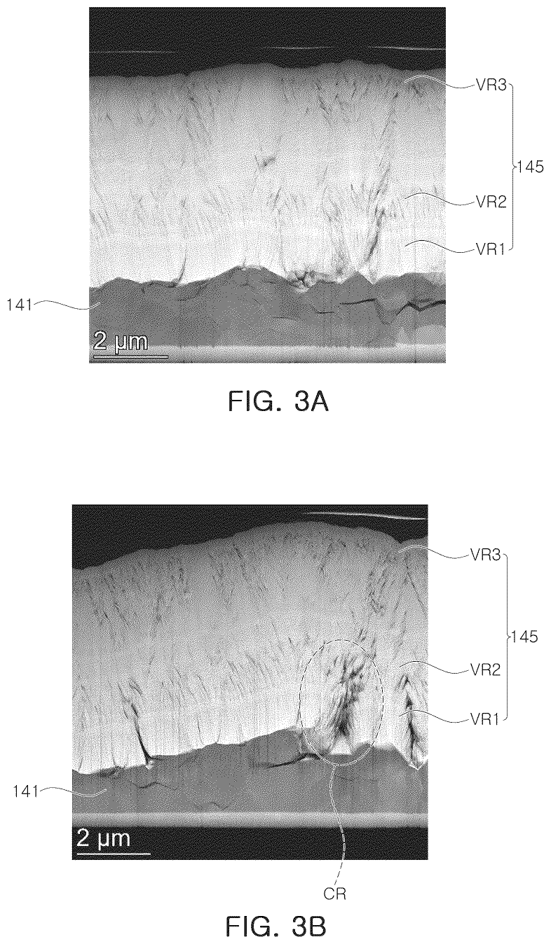

FIGS. 3A and 3B are SEM images of a coating film in a heater according to some implementations of the present disclosure and STEM images of a partially enlarged region.

Referring to FIG. 3A, a coating film 145 includes first to third vertical regions VR1, VR2, and VR3 having different crystal grain structures. The coating film 145 includes first to third vertical regions VR1, VR2, and VR3 sequentially stacked from an upper surface of the head portion 141. Among a plurality of vertical regions included in the coating film 145, an average size of crystal grains forming the second vertical region VR2 may be the greatest, and the crystal grains may have an anisotropic columnar crystal grain structure, and thus be arranged in a crystal grain structure extending in one direction (e.g., a vertical direction).

Referring to FIG. 3B, diffusion of cracks occurring when high-temperature heat is applied to the coating film 145 is prevented. The coating film 145 of the heater 140A according to the some implementations includes first to third vertical regions VR1, VR2, and VR3. Heat may be transferred from the high-temperature head portion 141 to the coating film 145, and in this case, a crack region CR may be formed in a portion of the first vertical region VR1, disposed at the bottom of the coating film 145, in direct contact with the head portion 141. A crack occurring in the first vertical region VR1 may extend to an interface between the first vertical region VR1 and the second vertical region VR2. The second vertical region VR2 may have an anisotropic columnar crystal grain structure, and such a structure may prevent cracks from extending onto the second vertical region VR2.

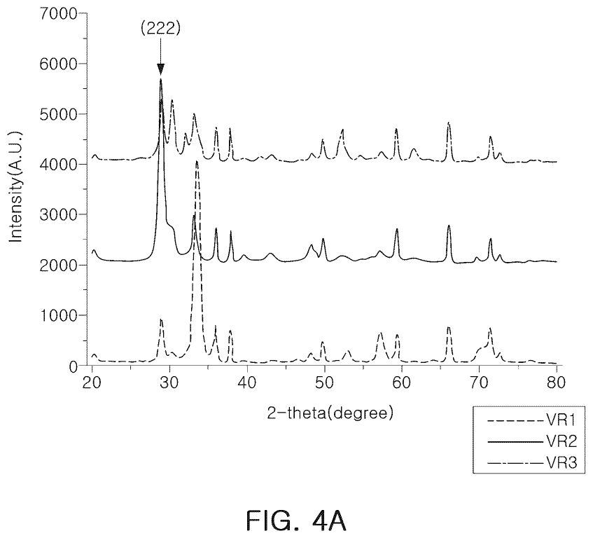

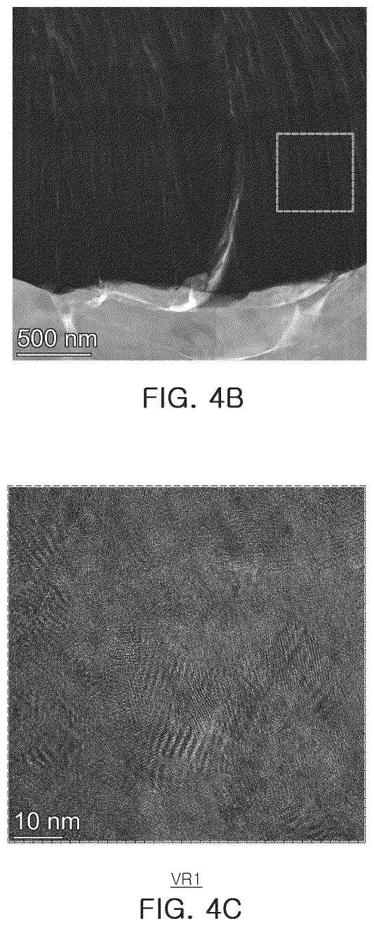

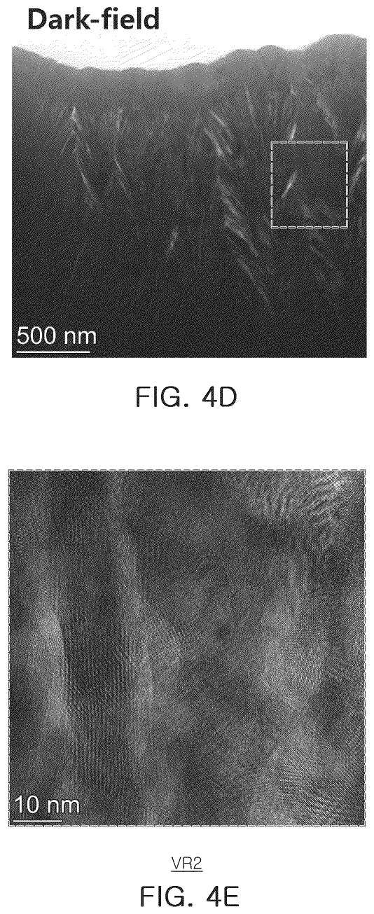

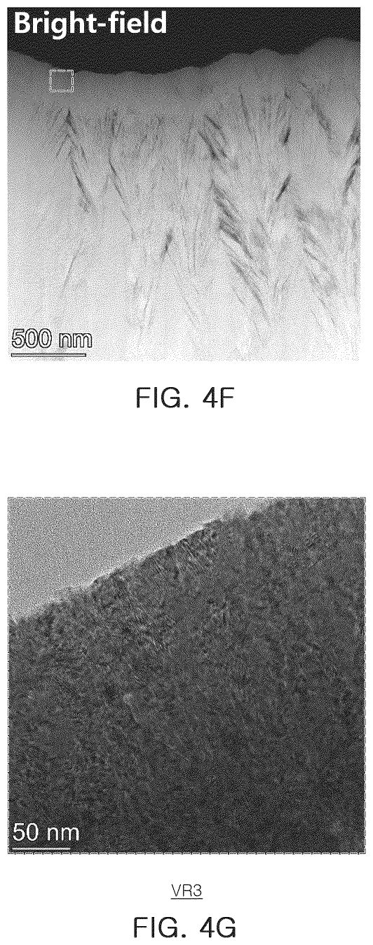

FIG. 4A is a graph of XRD data of first to third vertical regions of a coating film according to some implementations of the present disclosure, FIGS. 4B and 4C are TEM images obtained by taking a first vertical region, FIGS. 4D and 4E are TEM images obtained by taking a second vertical region, and FIGS. 4F and 4G are TEM images obtained by taking a third vertical region.

Referring to FIG. 4A, each of first to third vertical regions VR1, VR2, and VR3 may have different XRD data. Each of the first to third vertical regions VR1, VR2, and VR3 may have different crystallinity. Specifically, intensity of a XRD pattern in the second vertical region VR2 appears the strongest at a (2 2 2) crystal plane.

Referring to FIGS. 4B and 4C, arrangement of the first crystal grains G1 in the first vertical region VR1 may be confirmed. FIG. 4C may be a TEM image of an enlarged portion of the portion, indicated by a dotted line in FIG. 4B. Referring to FIGS. 4B and 4C, the first crystal grains G1 do not have a specific orientation and are randomly arranged. An average size of the first crystal grains G1 in the first vertical region VR1 may be about 10 nm to 25 nm, or about 10 nm to 20 nm, and in some implementations, an average size of the first crystal grains G1 in the first vertical region VR1 may be about 14 nm.

Referring to FIGS. 4D and 4E, arrangement of the second crystal grains G2 in the second vertical region VR2 may be confirmed. FIG. 4E may be a TEM image of an enlarged portion of the portion, indicated by a dotted line in FIG. 4D. Referring to FIGS. 4D and 4E, the second crystal grains G2 are arranged in a columnar shape extending in one direction. An average size of the second crystal grains G2 in the second vertical region VR2 may be about 30 nm to 80 nm, or about 30 nm to 70 nm, and in some implementations, an average size of the second crystal grains G2 in the second vertical region VR2 may be about 30 nm.

Referring to FIGS. 4F and 4G, arrangement of the third crystal grains G3 in the third vertical region VR3 may be confirmed. FIG. 4G may be a TEM image of an enlarged portion of the portion indicated by a dotted line in FIG. 4F. Referring to FIGS. 4F and 4G, the third crystal grains G3 do not have a specific orientation and are randomly arranged. An average size of the third crystal grains G3 in the third vertical region VR3 may be less than about 20 nm or less than about 10 nm, and in some implementations, an average size of the third crystal grains G3 in the third vertical region VR3 may be about 10 nm.

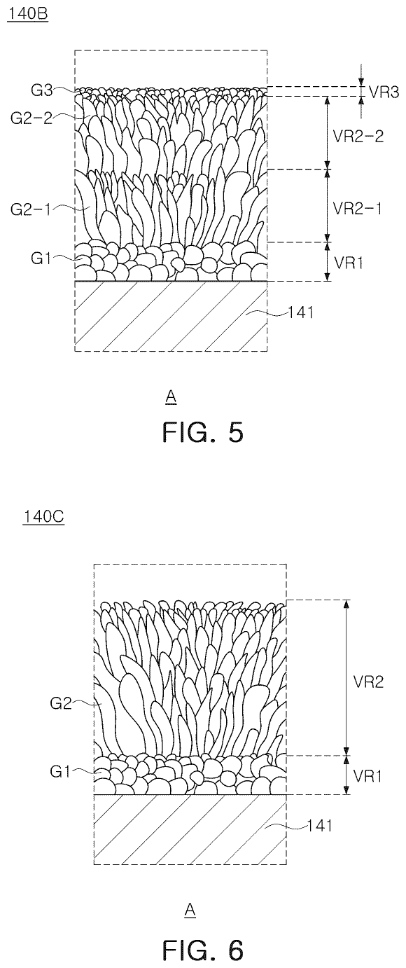

FIG. 5 is a partially enlarged view of region ‘A’ corresponding to FIG. 2C of the heater 140B according to some implementations of the present disclosure.

Referring to FIG. 5, a heater 140B according to the some implementations may have the same or similar characteristics as those described with reference to FIGS. 1 to 3B except that a second vertical region VR2 includes a lower region VR2-1 and an upper region VR2-2. The heater 140B according to some implementations includes a coating film 145 having four or more vertical regions. The coating film 145 may be disposed on an upper surface of the head portion 141, and the coating film 145 may be formed by sequentially stacking a first vertical region VR1, a lower region VR2-1, an upper region VR2-2, and a third vertical region VR3.

The lower region VR2-1 is a region disposed in the middle of the coating film, 145 and may be a region stacked on the first vertical region VR1. A lower surface of the lower region VR2-1 may be determined according to surface roughness of the first vertical region VR1. Crystal grains disposed in the lower region VR2-1 may be referred to as 2-1 crystal grains G2-1, and may have an anisotropic columnar crystal grain structure. The 2-1 crystal grains G2-1 may be arranged in a comb-patterned or fan-shaped structure from an interface of the first and lower regions VR1 and VR2-1.

The upper region VR2-2 may be a region stacked on the lower region VR2-1. A lower surface of the upper region VR2-2 may be determined according to surface roughness of the lower region VR2-1. Crystal grains disposed in the upper region VR2-2 may be referred to as 2-2 crystal grains G2-2, and may have an anisotropic columnar crystal grain structure. The 2-2 crystal grains G2-2 may be arranged in a comb-patterned or fan-shaped structure from an interface of lower and upper regions VR2-1 and VR2-2. An average size of the 2-2 crystal grains G2-2 may be greater than an average size of the 2-1 crystal grains G2-1, but the present disclosure is not limited thereto. The second vertical region VR2 of the heater 140B of some implementations is a region which prevents cracks from occurring in the coating film 145, and may include two or more regions. FIG. 6 is a partially enlarged view of region ‘A’ corresponding to FIG. 2C of a heater 140C according to some implementations of the present disclosure.

Referring to FIG. 6, the heater 140C according to some implementations may have the same or similar characteristics as those described with reference to FIGS. 1 to 5, except that a coating film 145 comprises a first vertical region VR1 and a second vertical region VR2.

The coating film 145 includes first and second vertical regions VR1 and VR2. The second vertical region VR2 may be a region located at the top of the coating film 145. An upper surface of the second vertical region VR2, a thickness of the coating layer 145 may be about 5 μm or more, about 6 μm or more and 15 μm or less, or about 7 μm or more and 10 μm or less, and a thickness ratio of the second vertical region VR2 to the entire coating film 145 may be about 65% or more and 90% or less, about 75% or more and 85% or less, or about 80%, but the present disclosure is not limited thereto. The second vertical region VR2 may serve to prevent cracks from occurring in the coating film 145 and to assist a wafer to be disposed stably.

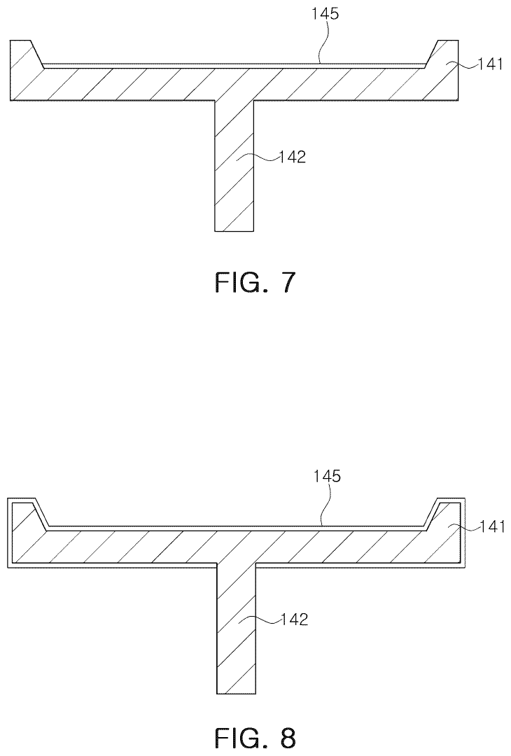

FIG. 7 is a cross-sectional view illustrating a heater 140D according to some implementations of the present disclosure.

Referring to FIG. 7, the heater 140D according to some implementations may have the same or similar characteristics as those described with reference to FIGS. 1 to 6, except that the coating film 145 is disposed in a first region R1 on an upper surface of the head portion 141. The coating film 145 may cover the upper surface of the head portion 141 within the first region R1. The first region R1 may be a region that can be defined by a wafer disposed on the head portion 141, and the coating film 145 may cover a region on which the wafer is disposed. The coating film 145 may prevent by-products from being formed during the process in the first region R1 in which the wafer is disposed, and may allow heat to be evenly transferred within the first region R1 of the head portion 141.

FIG. 8 is a cross-sectional view illustrating a heater 140E according to some implementations of the present disclosure.

Referring to FIG. 8, the heater 140E according to some implementations may have the same or similar characteristics as those described with reference to FIGS. 1 to 7, except that the coating film 145 is disposed along an outer circumference of the head portion 141 around the outer circumference of the head portion 141. In the heater 140E of some implementations, the coating film 145 may be disposed on at least a portion of a side surface and a lower surface of the head portion 141, including an upper surface of the head portion 141. The coating film 145 may serve to prevent by-products from being formed on a surface of the heater 140E during plasma processing. According to some implementations, the position in which the coating film 145 is formed on the heater 140E can be freely adjusted.

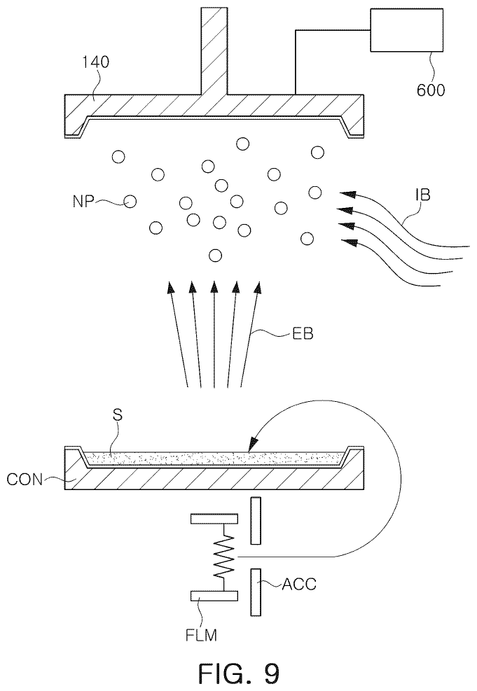

FIG. 9 is a schematic diagram schematically expressing a manufacturing process of the heater 140A according to some implementations of the present disclosure.

Referring to FIG. 9, a coating film 145 including first to third vertical regions VR1, VR2, and VR3 may be formed on a surface of the heater, using an electron beam (EB) module, an ion beam (IB) module, and a neutralizer 600.

A container (CON) containing a source material(S) containing a material to be deposited may be provided on the surface of the heater 140. For example, when the coating film 145 is Y₂O₃, the source material(S) may include yttrium (Y), along with other materials such as oxygen (O) and fluorine (F). The material to be deposited as the coating film 145 may be vaporized into fine particles (NP) by evaporating or sputtering. In this case, the evaporation or sputtering process may be performed through a series of processes in which electron particles emitted from a filament (FLM) pass through an accelerator (ACC) and then collide with the source material(S).

The source material(S) may exist in a form of vaporized fine particles (NP), and may cause deformation by causing the ion beam (IB) to collide with the surface of the heater 140 on which the coating film 145 is to be deposited. When the ion beam (IB) collides with the fine particles (NP), superplastic deformation may occur on the surface of the heater 140.

When superplastic deformation occurs on the surface of the heater 140, charge density provided can be adjusted by a neutralizer 600 connected to the heater 140. Depending on the operation of the neutralizer 600, superplastic deformation may occur, and a direction of crystal grains when fine particles (NPs) are deposited can be adjusted, and furthermore, when forming the coating film 145, the fine crystal grain structure can be implemented differently.

As set forth above, according to some implementations of the present disclosure, a heater having improved reliability and a plasma processing apparatus including the same may be provided by introducing a coating film covering at least a portion of an upper surface of the heater and having a multiple microstructure.

The various and advantageous advantages and effects of the implementations are not limited to the above description. While some implementations have been shown and described above, it will be apparent to those skilled in the art that modifications and variations could be made without departing from the scope of the disclosure, as defined by the appended claims.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While some implementations have been shown and described above, it will be apparent to those skilled in the art that modifications and variations could be made without departing from the scope of the disclosure as defined by the appended claims.

What is claimed is:

1. A heater, comprising:
a head portion having a first region and a second region disposed outside the first region;
a coating film covering at least a portion of an upper surface of the head portion; and
a support portion extending from a central portion of the first region of the head portion in a direction perpendicular to a lower surface of the head portion,
wherein the coating film includes
a first vertical region stacked on an upper surface of the head portion, the first vertical region having an isotropic texture structure;
a second vertical region stacked on an upper surface of the first vertical region, the second vertical region having a columnar crystal grain structure; and
a third vertical region stacked on an upper surface of the second vertical region, the third vertical region having an isotropic texture structure.

2. The heater of claim 1, wherein the head portion contains aluminum nitride (AlN).

3. The heater of claim 1, wherein the coating film is disposed on the upper surface of the head portion, within the first region.

4. The heater of claim 1, wherein an average size of crystal grains in the second vertical region is greater than an average size of crystal grains in the first vertical region.

5. The heater of claim 4, wherein the average size of the crystal grains in the first vertical region is about 10 nm to about 20 nm, and
the average size of the crystal grains in the second vertical region is about 30 nm to about 70 nm.

6. The heater of claim 1, wherein a thickness of the coating film is more than about 5 μm.

7. The heater of claim 1, wherein the second vertical region comprises a lower region stacked on the first vertical region and an upper region stacked on the lower region, and an average size of crystal grains in the upper region is greater than an average size of crystal grains in the lower region.

8. The heater of claim 1, wherein the coating film contains a yttrium (Y) compound.

9. The heater of claim 8, wherein the first to third vertical regions comprise a same material.

10. The heater of claim 1, wherein the first to third vertical regions have a same crystal phase.

11. The heater of claim 1, wherein an average size of the crystal grains in the first vertical region is greater than an average size of crystal grains in the third vertical region.

12. The heater of claim 11, wherein the average size of the crystal grains in the first vertical region is about 10 nm to about 20 nm, and the average size of the crystal grains in the third vertical region is less than about 10 nm.

13. The heater of claim 1, wherein a thickness of the second vertical region is greater than a thickness of the first vertical region.

14. The heater of claim 13, wherein a thickness ratio of the first vertical region to the coating film is about 15% to about 25%, and a thickness ratio of the second vertical region to the coating film is about 70% to about 80%.

15. The heater of claim 1, wherein a thickness ratio of the first vertical region to the coating film is about 15% to about 25%, and a thickness ratio of the third vertical region to the coating film is about 3% to about 10%.

16. The heater of claim 1, wherein an upper surface of the head portion within the first region is not exposed from the coating film.

17. A heater, comprising:
a head portion;
a coating film, wherein the coating film includes a support region formed of first crystal grains and covering at least a portion of the head portion, and includes a crack prevention region formed of second crystal grains and covering at least a portion of the support region; and
a support portion extending from the head portion in one direction,
wherein the second crystal grains have a length in a vertical direction greater than a length in a horizontal direction with respect to an upper surface of the head portion.

18. The heater of claim 17, wherein an average size of the second crystal grains is greater than an average size of the first crystal grains.

19. The heater of claim 17, wherein the coating film covers at least a portion of an outer surface of the head portion and covers at least a portion of a lower surface of the head portion.

20. A heater, comprising:
a head portion having a first region and a second region disposed outside the first region;
a coating film covering at least a portion of an upper surface of the head portion in the first region; and
a support portion extending from a central portion of the first region of the head portion in a direction perpendicular to a lower surface of the head portion,
wherein the coating film includes at least one region spaced apart from the upper surface of the head portion, wherein at least the one region formed of crystal grains arranged in a comb-patterned structure.
